(19) United States
(12) Patent Application Publication
(10) Pub. No.: US 2009/0201646 A1
(43) Pub. Date: Aug. 13, 2009

(54) RETAINING DEVICE

(75) Inventors: Chih-Kai YANG, Taipei (TW); Feng-Ku WANG, Taipei (TW)

Correspondence Address: Workman Nydegger;1000 Eagle Gate Tower, 60 East South Temple, Salt Lake City, UT, 84111, US

(73) Assignee: INVENTEC CORPORATION, Taipei (TW)

(21) Appl. No.: 12/029,780

(22) Filed: Feb. 12, 2008

(51) Int. Cl. H05K 7/20

(52) U.S. Cl. 361/704

(57) ABSTRACT

A retaining device is used to press a heat conducting plate to in contact with a heat-generating element disposed on a circuit board. The retaining device includes a bracket, a plurality of elastic members, and a plurality of fasteners. The bracket is disposed on a side surface of the circuit board while the bracket and the heat conducting plate are spaced by the circuit board. One end of the elastic members is disposed on the bracket. The fasteners pass through the heat conducting plate, the circuit board, and the bracket in sequence, so as to be fixed to the elastic members, such that the heat conducting plate is pressed by the elastic members to be continuously contact with the heat-generating element.

### BACKGROUND OF THE INVENTION

1. Field of Invention

The present invention relates to a retaining device, and more particularly to a retaining device for attaching a heating conducting plate to a heat-generating element of a circuit board.

2. Related Art

With the improvement of performance of computers, electronic elements in the computers, such as central processing units (CPUs) operates with high frequency of clock time, and the CPU are becoming smaller in size. Integrity on a unit area is increased, and the heat generating efficiency on a unit area of the electronic elements is also increased. If the heat is not dissipated in time, the over-high temperature will seriously affect the stability and efficiency of the operation of computers, and will shorten the life span of the electronic elements. Therefore, heatsinks for dissipating heat rapidly have become one of the indispensable members in computers.

A heatsink and an electronic component must be in contact with each other firmly and tightly, so as to reduce contact resistance of heat transfer and achieve fine heat dissipation performance. Conventionally, the heatsink is fixed by passing screws through the heatsink and fixing the screws into corresponding screw holes on a circuit board, such that the heatsink is in contacts with the electronic component tightly. However, a plurality of screws or bolts is required to fixing the heatsink on the electronic component firmly. When the heatsink is fixed to the circuit board, the circuit board or the heatsink often deforms as the locking forces of the bolts or screws are too great or uneven, or the heatsink often leaves the surface of the electronic component as the bolts or screws get loose.

As shown in FIGS. 1 and 2, in order to solve the problems that the heatsink is easy to leave the electronic component and the circuit board is easy to deform, a flat spring 11 is added above a heat conducting plate 21 of a heatsink 20, and a bracket 12 is disposed on the other side of a circuit board 30 opposite to the heatsink 20. The flat spring 11 is fixed to the bracket 12 with a plurality of bolts 13 passing through holes 14 and fixing holes 22, so as to provide a downward pressing force, such that the heat conducting plate 21 is pressed by the flat spring 11 to be in contact with an electronic element 31 disposed on the circuit board 30.

As the heatsink is pressed by the flat spring to be in contact with the electronic element, the problem generated when the heatsink is fixed to the circuit board with bolts or screws is solved. However, an additional flat spring must be used, which makes the assembling process complicated, lowers the production efficiency, and increases the production cost. Therefore, this method does not meet the current requirements of lower cost and higher production efficiency of the industry.

Moreover, ROC Patent No. M284952 discloses a retaining device of a heat dissipation mechanism, including a fixing member disposed on a heatsink base, a base disposed on a side of a mainboard, and at least one fastener pivoted on the base. The heatsink base is disposed on the other side of the main board opposite to the base, and the fixing member passes through the mainboard to be clamped by a plurality of pins of the fastener, such that the heatsink base is tightly in contact with the heat-generating element through the pressing force of the base.

Though Patent No. M284952 improves the tight attachment of the heatsink to the heat-generating element, it is the same as the prior art, in which the heatsink is pressed by the flat spring to be in contact with the electronic element, i.e., both adopt the design idea of combining two independent members to generate an urging force, so as to attach the heatsink to the heat-generating element.

If an elastic fixing element and a bracket body are combined into one piece, the fabricating cost will be lowered, and the assembling speed will be improved.

### SUMMARY OF THE INVENTION

In view of the above problems, the present invention provides a retaining device, so as to solve the problems that the retaining device of the heat sink uses two independent components, leading to complicated assembling process, higher production cost, and low production efficiency.

The retaining device of the present invention includes a bracket, a plurality of elastic members, and a plurality of fasteners, so as to press a heat conducting plate to be in contact with at least one heat-generating element disposed on a circuit board. Moreover, a plurality of fixing holes is formed in the heat conducting plate and the circuit board. The bracket is disposed on a side of the circuit board, wherein the bracket and the heat conducting plate is spaced by the circuit board, and a plurality of through holes is formed in the bracket corresponding to the fixing holes. One end of each of the elastic members is disposed on the bracket, and the other end has a locking hole. The fasteners pass through the fixing holes and the through holes in sequence, and are fixed in the locking holes, such that the bracket is combined with the circuit board, and the elastic members generate a force pressing the circuit board continuously, so as to pressing the heat conducting plate to be in contact with the heat-generating element.

In the retaining device of the present invention, the bracket and the elastic members are formed monolithically. Moreover, the retaining device generates a pressing force to the heat dissipation device having a heat conducting plate, such that the heat conducting plate is pressed to be in contact with to the heat-generating element normally. Thus, the present invention significantly reduces the number of components of the retaining device, lowers the production cost, and improves the production efficiency.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 is an exploded view of the prior art;

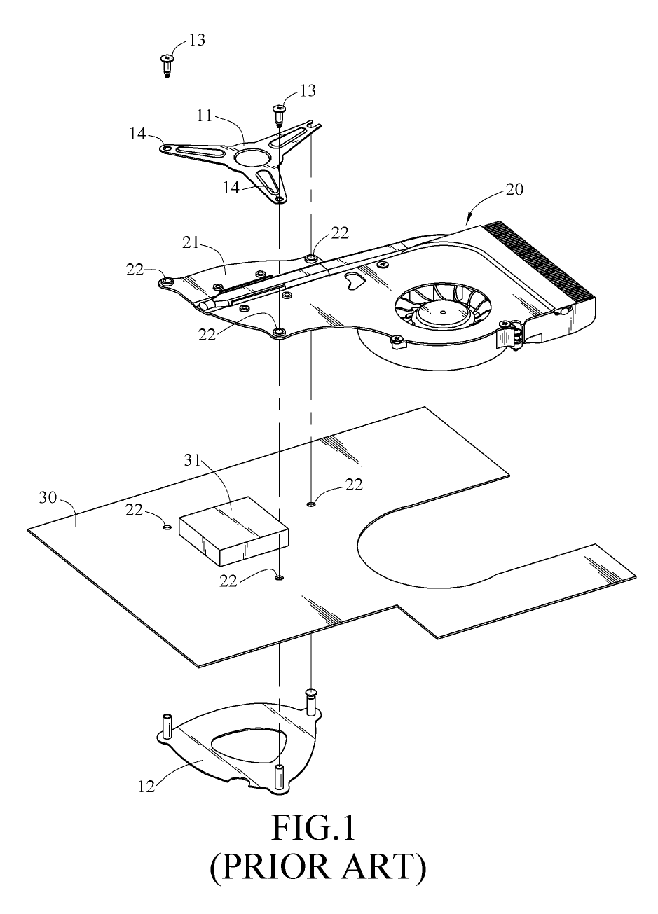

FIG. 2 is a perspective view of the prior art;

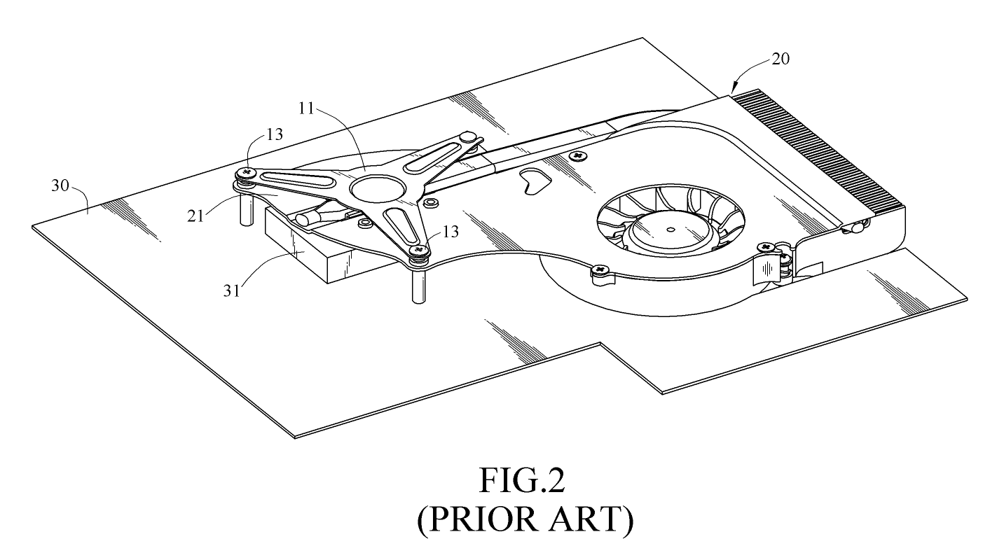

FIG. 3 is an exploded view of the first embodiment of the present invention;

FIG. 4 is a perspective view of the first embodiment of the present invention;

FIG. 5 is a side view of the first embodiment of the present invention;

FIG. 6 is an exploded view of the second embodiment of the present invention;

FIG. 7 is an exploded view of the third embodiment of the present invention; and

FIG. 8 is a perspective view of the third embodiment of the present invention.

### DETAILED DESCRIPTION OF THE INVENTION

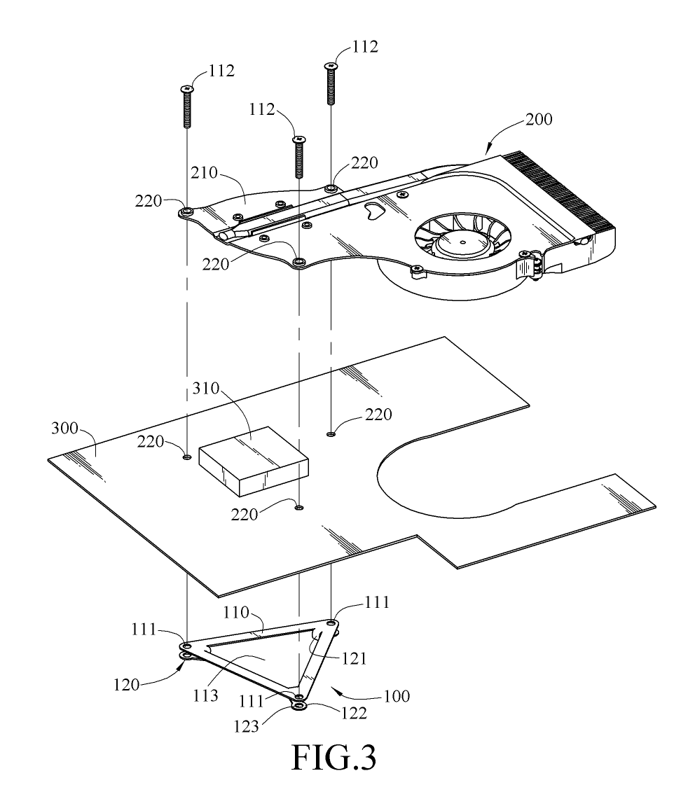

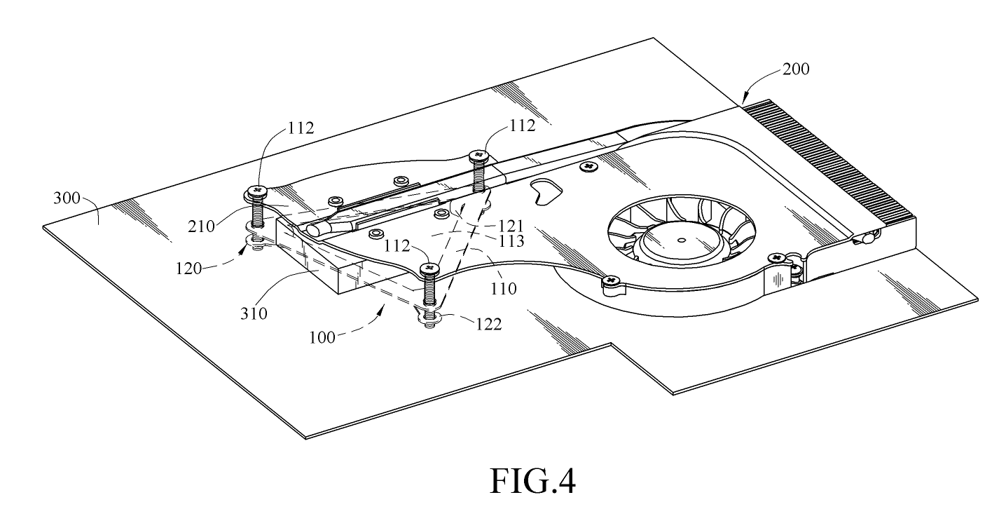

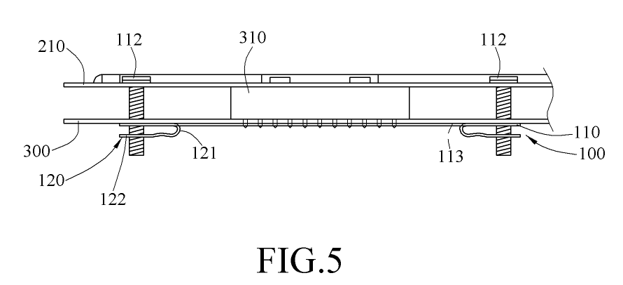

Referring to FIGS. 3, 4, and 5, a first embodiment of the present invention is illustrated. A retaining device 100 of the present invention is used to pressing a heat conducting plate 210 of a heatsink 200 to be in contact with a heat-generating element 310 disposed on a circuit board 300. The heat-generating element 310 is an electronic element that generates high heat, such as a south bridge chip, a north bridge chip, or a CPU. A plurality of fixing holes 220 is formed in the heat conducting plate 210 and the circuit board 300, wherein the fixing hole 220 of the heat conducting plate 210 are arranged corresponding those of the circuit board 300.

The retaining device 100 includes a bracket 110, a plurality of elastic members 120 disposed on the bracket 110 and spaced at even angles, and a plurality of fasteners 112. The bracket 110 is disposed on a side of the circuit board 300, wherein the bracket 110 and the heat conducting plate 210 are spaced by the circuit board 300. The bracket 110 has a plurality of through holes 111 corresponding to the fixing holes 220. An end of each of the elastic members 120 is disposed on the bracket 110. The bracket 110 has a compressible section 121 and a bent section 122. The compressible section 121 extends from the bracket 110 while the bent section extends from the compressible section 121 to suspend above the bracket 110. A locking hole 123 is formed in the bent section 122 corresponding to the through hole 111 and the fixing hole 220. The number and positions of the elastic members 120, the through holes 111, and the fasteners 112 are determined according to actual requirements in use, and the number is not limited to be three as disclosed in this embodiment.

The fasteners 112 pass through the fixing holes 220 and the through holes 111 in sequence, and are fixed in the locking holes 123, such that one side of the bracket 110 is in contact with the circuit board 300. The compressible sections 121 of the elastic members 120 are pressed to be deformed by the downward force applied by the fasteners 112, so as to generate an elastic force. The bent sections 122 are pressed by the elastic force toward the circuit board 300, so as to press the heat conducting plate 210 to be in contact with the heat-generating element 310 normally, thereby achieving preferred heat dissipation performance.

The fasteners 112 of the present invention provide a holding force, such that the heat conducting plate 210, the circuit board 300, and the retaining device 100 are combined together. In this embodiment, the fasteners 112 are bolts. However, a person skilled in the art can use any component that can provide the fixing function, such as pins or rivets, which are not limited to the embodiment of the present invention.

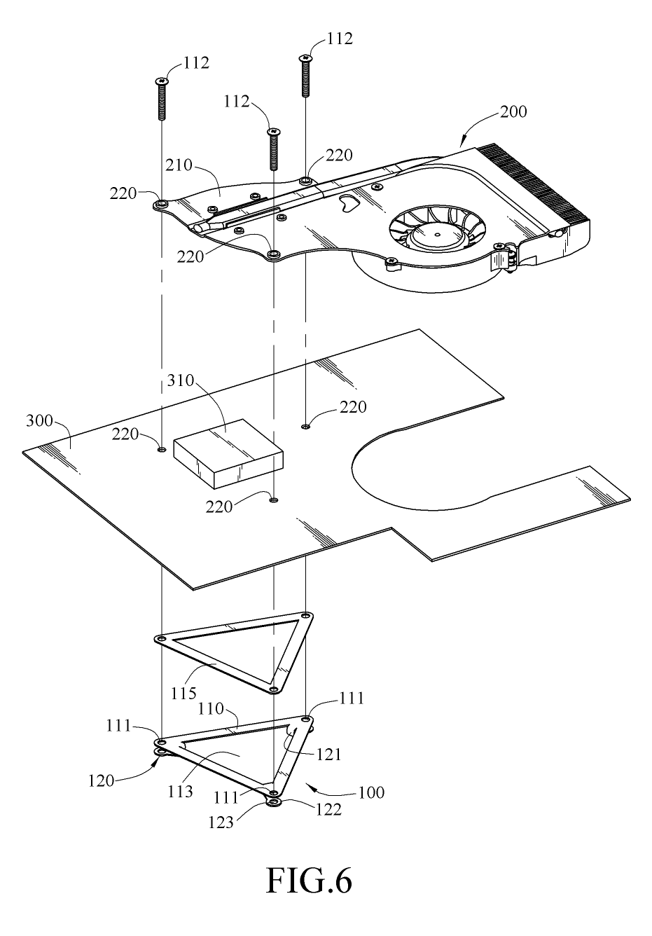

Referring to FIGS. 3, 4, and 5 again, a hollow area 113 is formed at a central position of the bracket 110 of the present invention. The hollow area 113 is used to accommodate electrical contacts on the circuit board 300, such that the bracket 110 is completely in contact with the circuit board 300. In order to prevent short circuit caused by the contact between the bracket 110 and the circuit board 300, the bracket 110 of the present invention is made of an insulating material, or as shown in FIG. 6, an insulating pad 115 is disposed on a side of the bracket 110 wherein the side faces the circuit board 300, so as to prevent the short circuit of the circuit board 300.

As shown in FIG. 3, the elastic members 120 of the present invention extend from the inner edge of the hollow area 113 to form the compressible sections 121, and the bent sections 122 extend toward the outer edge of the bracket 110; or the elastic members 120 extend from the outer edge of the bracket 110 to form the compressible sections 121, and the bending members 122 extend toward the inner edge of the hollow area 113 in suspension. In addition, the elastic members 120 are formed on the inner edge of the hollow area 113 or the outer edge of the bracket 110 by means of rivet connection or punching.

As for the elastic members 120, the material and shape required to form the elastic members 120 are reserved at the mean time as the hollow area 113 is formed, and the elastic members 120 bend outward from the inner edge of the hollow area 113. The elastic members 120 thus formed reduce the material amount to produce the retaining device 100 significantly, and reduce the overall production cost as well.

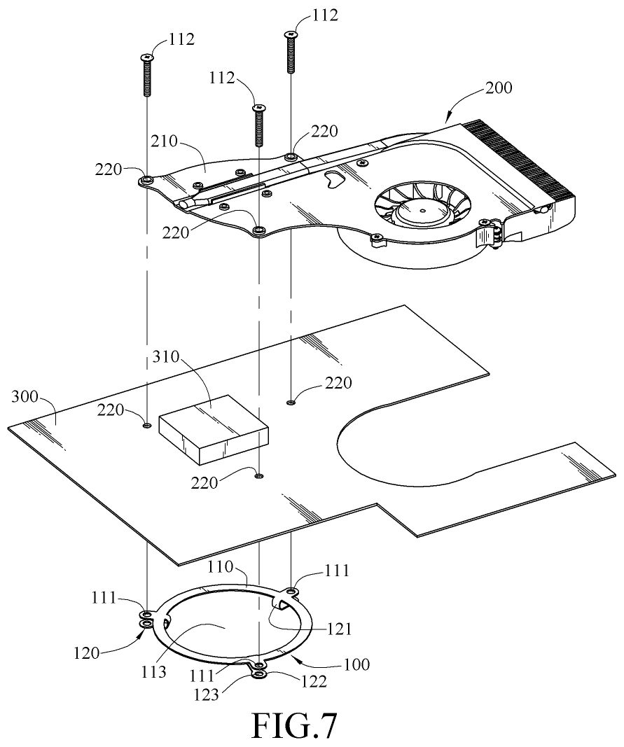

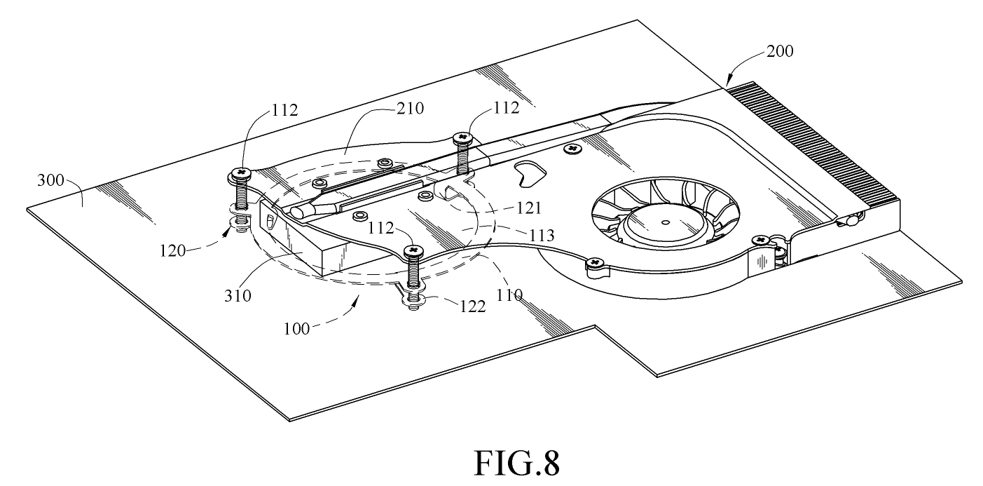

In addition to the triangular shape of FIG. 3, the bracket 110 of the present invention can be designed round as shown in FIGS. 7 and 8, so as to satisfy the requirements on circuit layout of different types of circuit boards 300. A person skilled in the art can also modify the bracket 110 to a shape matching the circuit board 300, such as square, polygon, or an irregular shape, which is not limited to this embodiment.

The retaining device of the present invention is formed monolithically, which reduces the number of components of the retaining device, lowers the production cost, and improves the production efficiency. Thus, the problem of the prior art that combines two independent members is solved. Moreover, the material required to form the elastic members is reserved at the mean time as the hollow area of the bracket is formed, and the elastic members bend outward from the inner edge of the hollow area. Thus, the material to produce the retaining device is reduced significantly, and the overall production cost is lowered as well.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A retaining device, for pressing a heat conducting plate to be in contact with a heat-generating element disposed on a circuit board, wherein a plurality of fixing holes is formed in the heat conducting plate and the circuit board, the retaining device comprising:
a bracket, disposed on a side of the circuit board, wherein the bracket and the heat conducting plate are spaced by the circuit, and a plurality of through holes is formed in the bracket corresponding to the fixing holes of the circuit board and the heat conducting plate;
a plurality of elastic members, wherein an end of each of the elastic members is disposed on the bracket, and the other end has a locking hole; and
a plurality of fasteners, passing through the fixing holes and the through holes to be locked in the locking holes, such that the heat conducting plate is pressing by the elastic members to be continuously in contact with heat-generating element normally.

2. The retaining device as claimed in claim 1, wherein the elastic member having a compressible section extending from the bracket and a bent section extending from the compressible section to suspend above the bracket, wherein the locking hole is formed in the compressible section.

3. The retaining device as claimed in claim 2, wherein the bracket has a hollow area, and the compressible sections extend from an inner edge of the hollow area.

4. The retaining device as claimed in claim 1, wherein the bracket is made of insulating material.

5. The retaining device as claimed in claim 1, wherein an insulating pad is disposed on a side of on the bracket, wherein the side faces the circuit board.
